(19) United States
(12) Patent Application Publication
(10) Pub. No.: US 2005/0149783 A1
(43) Pub. Date: Jul. 7, 2005

(54) Methods and apparatus for testing an IC

(75) Inventors: Wayne A. Britson, Rochester, MN (US); Daniel A. Flores-Ibarra, Rochester, MN (US)

Correspondence Address: IBM CORPORATION;ROCHESTER IP LAW DEPT. 917, 3605 HIGHWAY 52 NORTH, ROCHESTER, MN, 55901-7829, US

(73) Assignee: INTERNATIONAL BUSINESS MACHINES CORPORATION, ARMONK, NY (US)

(21) Appl. No.: 10/733,693

(22) Filed: Dec. 11, 2003

(51) Int. Cl. G11B 5/00; G06K 5/04; G01R 31/28; G11B 20/20

(52) U.S. Cl. 714/724

(57) ABSTRACT

In a first aspect, a first method is provided for testing an integrated circuit (IC). The first method includes the steps of (1) employing one of a plurality of input lines to receive a test signal for a processor; (2) employing one of a plurality of output lines to send a test result from the processor; and (3) if the test result is unsuccessful, performing at least one of employing a remaining one of the plurality of input lines to receive the test signal for the processor and employing a remaining one of the plurality of output lines to send the test result from the processor. Numerous other aspects are provided.

### FIELD OF THE INVENTION

The present invention relates generally to integrated circuits, and more particularly to methods and apparatus for testing integrated circuits.

### BACKGROUND

An integrated circuit (IC), such as a card coupled to a computer, or a multi-chip module included in a larger IC may include one or more processors. The IC may include circuitry for testing and/or monitoring the one or more processors. For example, Joint Test Action Group (JTAG) circuitry may be used to test the processors during system initialization. More specifically, signals (e.g., JTAG signals) may be input and/or output by the processors using lines (e.g., JTAG lines) included in the test circuitry (e.g., JTAG circuitry).

If one or more of the test circuitry lines (e.g., JTAG lines) include a break or are short-circuited, the test performed on the one or more processors will fail. More specifically, a failure in one or more of the test circuitry lines may force the system that includes the IC to terminate an initial program load (IPL), which performs diagnostic tests and determines the identification of the one or more processors included in the IC. Such a failure of a test circuitry line included in an IC may reduce the life of the card which includes the IC and may reduce a production yield during card manufacturing.

Because redundancy is provided for hardware included in the IC and/or the card which includes the IC, the failure rate for such hardware is reduced. Consequently, the percentage of IC failures due to faulty lines (e.g., JTAG lines) is increased. Methods and apparatus are desired for minimizing IC line failures.

### SUMMARY OF THE INVENTION

In a first aspect of the invention, a first method is provided for testing an integrated circuit (IC). The first method includes the steps of (1) employing one of a plurality of input lines to receive a test signal for a processor; (2) employing one of a plurality of output lines to send a test result from the processor; and (3) if the test result is unsuccessful, performing at least one of employing a remaining one of the plurality of input lines to receive the test signal for the processor and employing a remaining one of the plurality of output lines to send the test result from the processor.

In a second aspect of the invention, a first apparatus is provided that includes a processor, a plurality of input lines coupled to the processor, a plurality of output lines coupled to the processor, and a connector interface coupled to the plurality of input lines and the plurality of output lines. The apparatus may be adapted to (1) employ one of the plurality of input lines to receive a test signal for the processor; (2) employ one of the plurality of output lines to send a test result from the processor; and (3) if the test result is unsuccessful, perform at least one of employing a remaining one of the plurality of input lines to receive the test signal for the processor and employing a remaining one of the plurality of output lines to send the test result from the processor. Numerous other aspects are provided, as are systems and apparatus in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 is a block diagram of an exemplary circuit for testing an IC in accordance with an embodiment of the present invention.

FIG. 2 illustrates an exemplary method of testing an IC in accordance with an embodiment of the present invention.

FIG. 3 is a block diagram of a second exemplary circuit for testing an IC in accordance with an embodiment of the present invention.

### DETAILED DESCRIPTION

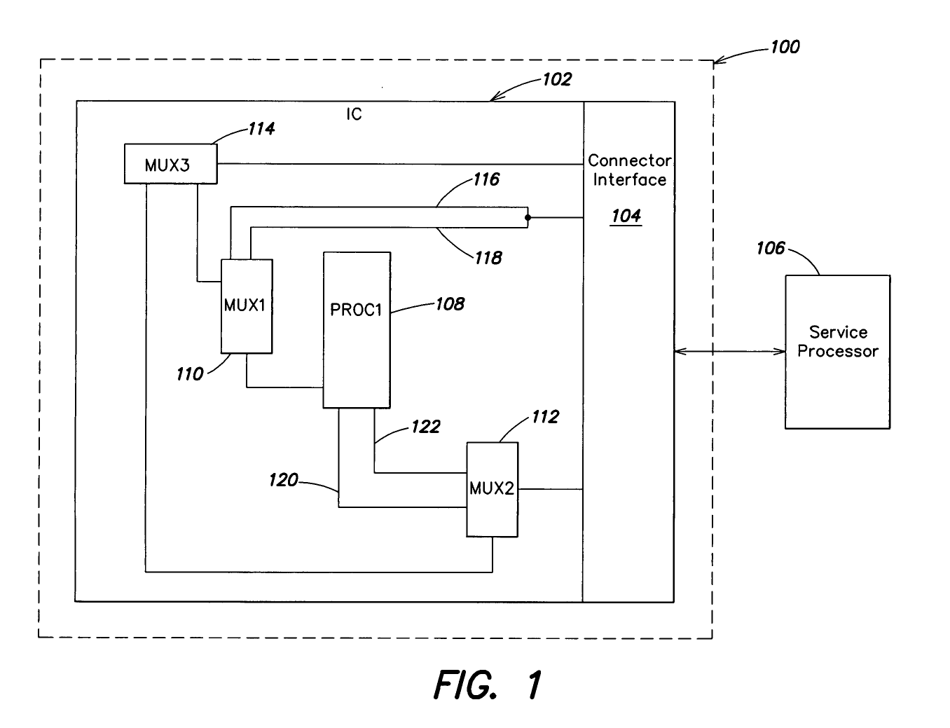

FIG. 1 is a block diagram of an exemplary circuit 100 for testing an IC 102 in accordance with an embodiment of the present invention. The exemplary circuit 100 may be included in a card which may be coupled to a computer. The IC 102 included in the exemplary circuit 100 may be coupled via a connector interface 104 to a service processor 106, which may provide test signals and/or patterns of data to the exemplary circuit 100. More specifically, the service processor 106 may provide a test and/or data signal to the connector interface 104, which provides the test signal and/or data to the IC 102 (e.g., via a pin included in the connector interface 104).

The IC 102 may include one or more processors 108 (only one shown in FIG. 1), which may be customized by a consumer, for executing instructions and receiving the test signals and patterns of data from the service processor 106. The one or more processors 108 may each be coupled to one or more multiplexers. More specifically, the IC 102 may include a processor 108 coupled to an output of a first multiplexer 110 and one or more inputs of a second multiplexer 112. The first multiplexer 110 may be coupled to a third multiplexer 114, both of which are coupled to the connector interface 104. The first multiplexer 110 may receive an input signal (e.g., the test and/or data signal) from the connector interface 104 via each of a plurality of input lines 116, 118 coupled to the connector interface 104, and receive an input signal (e.g., a first select signal) from the third multiplexer 114. Because the third multiplexer 114 is coupled to the connector interface 104, which may be coupled to the service processor 106, select signals which are output by the third multiplexer 114 may be based on bits provided to the third multiplexer 114 by the service processor 106. One of the test and/or data signals input by the first multiplexer 110 via each of the plurality of input lines 116, 118 may be selectively output to the processor 108 based on the first select signal input by the first multiplexer 110. In one embodiment, the first multiplexer 110 is coupled to two input lines thereby providing 2-to-1 multiplexing. The first multiplexer 110 may be coupled to other numbers of input lines 116, 118 and therefore provide a different amount of multiplexing.

The processor 108 may be coupled to the second multiplexer 112 via a plurality of output lines 120, 122 of the processor 108, which may serve as input lines for the second multiplexer 112. The second multiplexer 112 may be coupled to the connector interface 104 and the third multiplexer 114. More specifically, the second multiplexer 112 may receive an input signal (e.g., a test result), which is output by the processor 108 on each of the plurality of output lines 120, 122 and receive an input signal (e.g., a second select signal) from the third multiplexer 114. The test result input by the second multiplexer 112 from one of the plurality of output lines 120, 122 of the processor 108 may be selectively output to the connector interface 104 based on the second select signal input by the second multiplexer 112 (and provided by the third multiplexer 114). In one embodiment, the second multiplexer 112 is coupled to two output lines 120, 122, and outputs a signal on a single line, thereby providing 2-to-1 multiplexing. The second multiplexer 112 may be coupled to other numbers of output lines 120, 122 of the processor 108, which may serve as input lines for the second multiplexer 112, and therefore may provide a different amount of multiplexing.

The test result selectively output by the second multiplexer 112 may be provided to the connector interface 104 (e.g., via a pin included in the connector interface 104). Because the connector interface 104 is coupled to the service processor 106, the test result may be provided to the service processor 106. In this manner, the exemplary circuit 100 for testing an IC 102 may receive one or more test and/or data signals and one or more select signals, and output a test result.

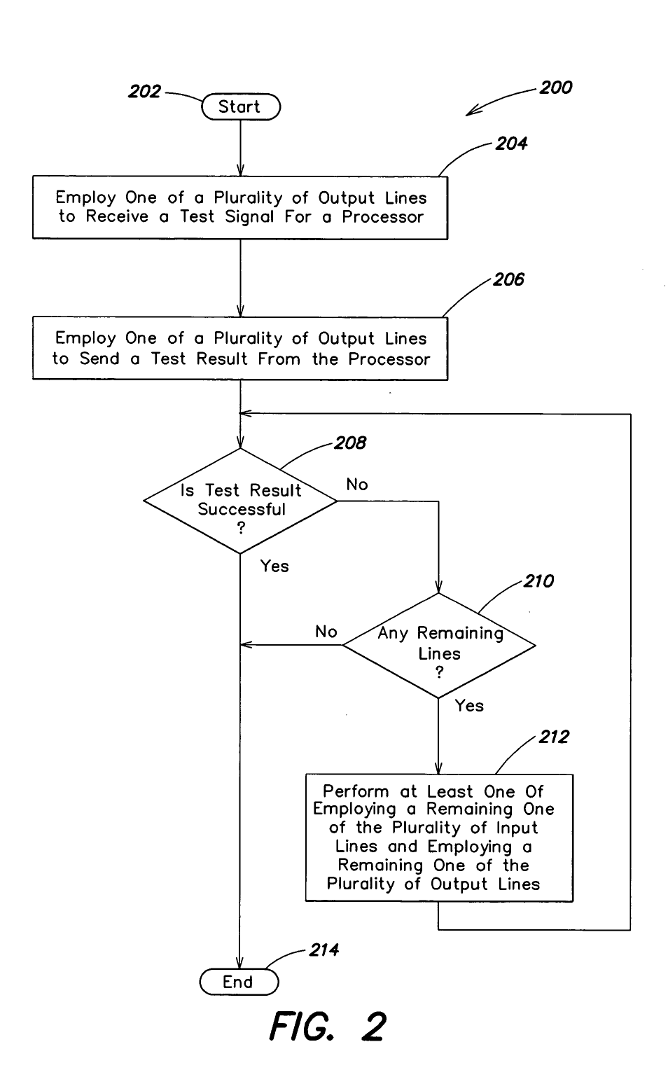

The operation of the exemplary circuit 100 for testing an IC 102 is now described with reference to FIG. 1 and with reference to FIG. 2 which illustrates an exemplary method of testing an IC 102 in accordance with an embodiment of the present invention. With reference to FIG. 2, in step 202, the method 200 begins. In step 204, one of a plurality of input lines may be employed to receive a test signal for a processor. For example, upon executing code included in the service processor 106, the service processor 106 may provide a test signal and/or data, such as a known pattern, to the processor 108 via the connector interface 104. The connector interface 104 may receive the test signal and/or data from the service processor 106 and output the test signal and/or data from a connector interface 104 pin coupled to a plurality of input lines 116, 118 included in the circuit 100 for testing an IC 102. Therefore, the connector interface 104 may apply the test signal and/or data to each of the plurality of input lines 116, 118.

The service processor 106 may also issue a serial command (e.g., an Inter-IC (IIC) command) to provide one or more bits to the circuit 100 for testing the IC 102. More specifically, the connector interface 104 may receive one or more bits via a serial transmission from the service processor 106, and transmit the one or more bits via a pin included in the connector interface 104 to the third multiplexer 114. The third multiplexer 114 may receive the one or bits as input signals and output one or more bits, which serve as select signals. In one embodiment, the connector interface 104 receives a number of bits that corresponds to the number of multiplexers, which receive a test signal and/or data or output a test result, included in the IC 102.

The first multiplexer 110 may receive the test signal and/or data from each of the plurality of input lines 116, 118 as input. One of the plurality of input lines 116, 118 may be selected. More specifically the first multiplexer 110 may also receive one of the signals output by the third multiplexer 114 as an input (e.g., a select signal input). Based on the select signal input by the first multiplexer 110, one of the plurality of input lines 116, 118 is selected. As stated above, in one embodiment, the circuit 100 for testing an IC 102 may include two input lines coupled to each multiplexer which receive a test signal and/or data from the service processor 106. A first input line 116 may be employed as a primary input line and a second input line 118 may be employed as a secondary input line. Other numbers of input lines may be employed.

The test signal and/or data on the selected input 116, 118 may be received for the processor 108. More specifically, the test signal on the selected one of the primary or secondary input line 116, 118 may be output by the first multiplexer 110 and transmitted to the processor 108.

In step 206, one of a plurality of output lines may be employed to send a test result from the processor. For example, in addition to sending a test signal and/or data to the first multiplexer 110, the service processor 106 may execute code requesting the processor 108 to output a processor identification (ID) and the test signal and/or data (e.g., the known pattern) received by the processor 108, which may serve as the test result. The processor ID may include information such as which processor 108 is included in the IC 102 and where the processor 108 is made. In other embodiments, other types of data may serve as the test result.

The processor 108 may apply the test result to each a plurality of output lines 120, 122 coupled to the processor 108. Because the plurality of output lines 120, 122 are coupled to and provide input to the second multiplexer 112, the second multiplexer 112 may receive the test result from each of the plurality of output lines 120, 122 as input. One of the plurality of output lines 120, 122 may be selected. More specifically, similar to the first multiplexer 110, the second multiplexer 112 may receive one of the signals output by the third multiplexer 114 as an input signal (e.g., a second select signal). Based on the second select signal input by the second multiplexer 112, one of the plurality of output lines 120, 122 may be selected. In one embodiment, the circuit 100 for testing IC 102 may include two output lines coupling the processor 108 to each multiplexer (e.g., the second multiplexer 112) that receives a test result from the processor 108. A first output line 120 may be employed as a primary output line and a second output line 122 may be employed as a secondary output line. Other numbers of output lines may be employed.

The test result received from the selected output line 120, 122 may be transmitted. More specifically, the test result received by the second multiplexer 112 as input from the selected one of the primary or the secondary output line may be output by the second multiplexer 112 and sent to the connector interface 104. The connector interface 104 may send the test result to the service processor 106.

In this manner, the exemplary circuit 100 for testing an IC 102 may receive the test signal and/or data from the service processor 106 and output the test result to the service processor 106.

In step 208, it is determined whether the result of the test performed on the IC 102 was successful. The test result output by the IC 102 may be compared to the test signal and/or data input by the IC 102. For example, the service processor 106 may execute code to compare a pattern of data output by the IC 102 as a portion of a test result with a known pattern of data that is input by the IC 102. If the pattern of data provided to the IC 102 matches the pattern of data output by the IC 102 as a portion of the test result, the processor 108 and at least one input line 116, 118 and one output line 120, 122 coupled to the processor 108 are valid and the test result is successful. In step 208, if it is determined that the test result is successful, step 214 is performed. In step 214, the method 200 ends.

Alternatively, if it is determined in step 208 that the result of the test performed on the IC 102 is unsuccessful, step 210 may be performed. The result of the test performed on the IC 102 may be unsuccessful if a portion of the test result (e.g., a pattern of data) output by the IC 102 does not match a portion of the test signal and/or data input by the IC 102. For example, in response to receiving as input a pattern of data, such as a plurality of non-zero characters, from the service processor 106, the IC 102 may output a plurality of zeroes or one or more processor IDs and a plurality of zeroes as a test result to the service processor 106. Upon comparing the test result with the input test signal and/or data, the service processor 106 may determine the result of the test performed on the IC 102 was unsuccessful. Although in the above embodiments, the service processor 106 compares the test result with the input test signal and/or data, in other embodiments, other devices coupled to and/or included in the IC 102 may be used for comparing a portion of the test result to a portion of the input test signal and/or data. An unsuccessful result of the test performed on the IC 102 may indicate a failure in one or more input lines 116, 118 and/or one or more output lines 120, 122 included in the IC 102.

In step 210, it is determined whether a remaining one of the plurality of input lines may be employed to receive the test signal and/or data (e.g., for the processor 108) or a remaining one of the plurality of output lines may be employed to send the test result from the processor 108. Select signals output by the third multiplexer 114 determine which input line 116, 118 and output line 120, 122 are employed by the IC 102. As stated, the select signals output by the third multiplexer 114 are based on bits (e.g., a serial transmission of bits) provided to the third multiplexer 114 by the service processor 106. Therefore, the service processor 106 may determine whether a remaining one of the plurality of input lines may be employed to recieve the test signal and/or data for the processor 108 or a remaining one of the plurality of output lines may be employed to send the test result from the processor 108. The service processor 106 may modify the bits provided to the third multiplexer 114 based on bits previously sent to the IC 102 during the same or a previous test. If it is determined, in step 210, a remaining one of the plurality of input lines may be employed to receive the test signal and/or data for the processor 108 or a remaining one of the plurality of output lines may be employed to send the test result from the processor 108, step 212 may be performed.

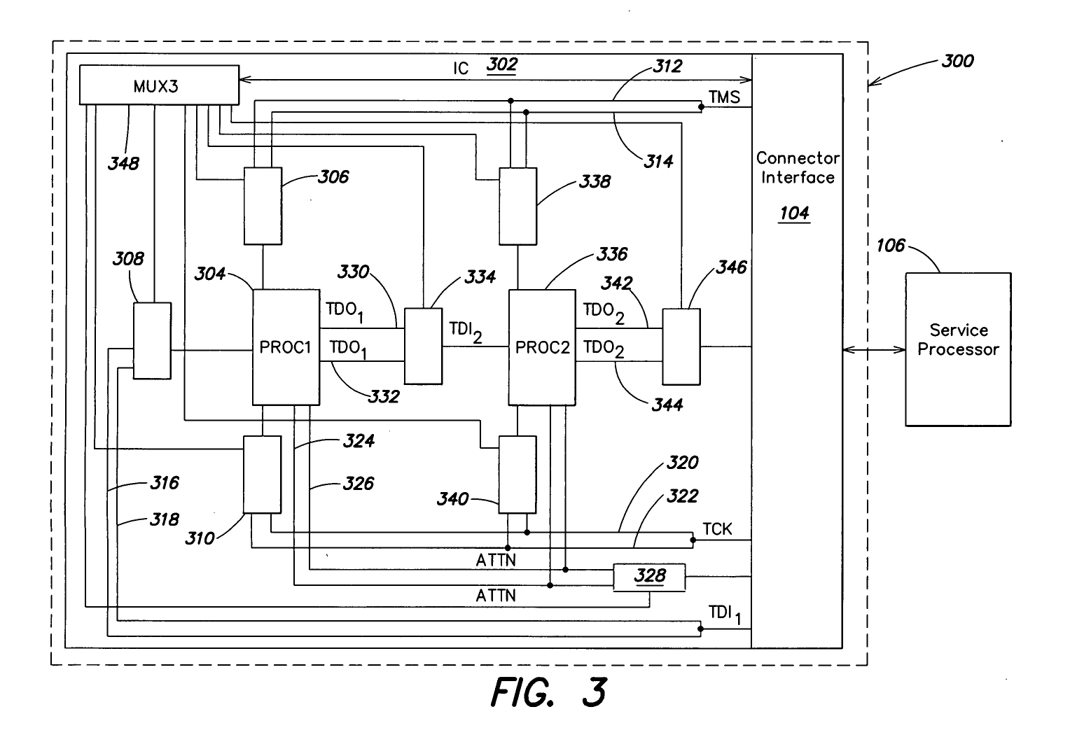

In step 212, at least one of employing a remaining one of the plurality of input lines to receive the test signal and/or data for the processor and employing a remaining one of the plurality of output lines to send the test result from the processor is performed. The service processor 106 may provide modified bits, via a serial transmission, to the third multiplexer 114. The modified bits may be transmitted in response to an IIC command from the service processor 106. Based on such modified bits, the third multiplexer 114 may output signals (e.g., modified select signals) that determine which input line 116, 118 and which output line 120, 122 are employed by the IC 102. Therefore, by modifying the bits provided to the third multiplexer 114, the service processor 106 may employ a remaining one of the plurality of input lines to receive the test signal for the processor and/or employ a remaining one of the plurality of output lines to send the test result from the processor 108. The service processor 106 may use an algorithm to modify the bits provided to the third multiplexer 114. One such algorithm is described below with reference to FIG. 3. In this manner, the test may be performed on the IC 102 using a different combination of input 116, 118 and output lines 120, 122. Thereafter, step 208 is performed. If employing a particular combination of input 116, 118 and output lines 120, 122 yields a successful test result, the bits provided to the third multiplexer 114 by the service processor 106 to employ the particular combination may be saved such that the same bits may be provided to the third multiplexer 114 in subsequent IPLs.

Alternatively, if it is determined, in step 210, that no input lines that may be employed to receive the test signal and/or data for the processor 108 remain, and no output lines that may be employed to send the test result from the processor 108 remain, the code executed by the service processor 106 may determine that the IC 102 or the card which includes the IC 102 is faulty and output an error.

Thereafter, step 214 may be performed. As stated above, in step 214, the method 200 ends. Through use of the method 200 of testing an IC 102, in response to an unsuccessful test result using a combination of one of a plurality of input lines and one of a plurality of output lines included in an IC 102, a different combination of an input line and an output line may be employed until the test result is successful. In this manner, by providing redundancy in the input lines used for receiving a test signal and/or data for the processor and redundancy in the output lines used for transmitting a test result from the processor, the IC and/or card which includes the IC will not fail if one of the input lines and/or one of the output lines fails (e.g., because of a short circuit or a break in the line). Therefore, the present methods and apparatus may increase the manufacturing yield of the IC or the card which includes the IC. In one embodiment, the above methods may be performed during an initial program load (IPL) performed by the service processor 106. The above methods may be performed during other times.

FIG. 3 is a block diagram of a second exemplary circuit 300 for testing an IC 302 in accordance with an embodiment of the present invention. The second exemplary circuit 300 may be coupled to and tested using test circuitry, such as I.E.E.E. JTAG test circuitry. The second exemplary circuit 300 may receive JTAG test signals, such as Test Data Input (TDI), Test Clock (TCK) and Test Master Select (TMS) from the JTAG test circuitry and may transmit signals (e.g., test results), such as Test Data Output (TDO) and Attention (ATTN) to the JTAG test circuitry.

The second exemplary circuit 300 for testing an IC 302 is similar to the first exemplary circuit 100. However, the second exemplary circuit 300 may include a plurality of processors, each of which may receive a plurality of test signals and output a plurality of test results. More specifically, the second exemplary circuit 300 may be coupled, via a connector interface 104, to the service processor 106, which may include portions of the JTAG circuitry and send JTAG test signals to the second exemplary circuit 300. Other portions of the JTAG test circuitry may be included in the exemplary circuit 300 and/or a card which includes the exemplary circuit 300. The second exemplary circuit 300 may include a first processor 304 coupled to the connector interface 104 via a plurality of multiplexers. More specifically, the first processor 304 may be coupled to the output of a first, second and third multiplexer 306, 308, 310 included in the IC 302. The first multiplexer 306 may be coupled to and receive input from a first plurality of input lines 312, 314, which may be coupled to the connector interface 104 via a first pin, for example. Similarly, the second multiplexer 308 may be coupled to and receive input from a second plurality of input lines 316, 318, which may be coupled to the connector interface 104 via a second pin and the third multiplexer 310 may be coupled to and receive input from a third plurality of input lines 320, 322, which may be coupled to the connector interface 104 via a third pin, for example. The connector interface 104 may receive from the service processor 106, and transmit from the first, second, and third pins (not shown), respectively, JTAG test signals TMS, TDI₁, and TCK.

The first processor 304 may be coupled to a first plurality of output lines 324, 326, which are coupled to and provide signals, such as ATTN, respectively, output by the first processor 304 to a fourth multiplexer 328 as input. Therefore, the first plurality of output lines 324, 326 of the first processor 304 may serve as input lines for the fourth multiplexer 328. The fourth multiplexer 328 may be coupled to and provide an output signal to the connector interface 104 via a fourth pin. The connector interface 104 may provide the output signal to the service processor 106.

The first processor 304 may be coupled to a second plurality of output lines 330, 332, which are coupled to and may provide signals (e.g., TDO₁) output by the first processor 304 to a fifth multiplexer 334, respectively. Therefore, the second plurality of output lines 330, 332 may serve as input lines for the fifth multiplexer 334. The fifth multiplexer 334 may be coupled to and output a signal, such as TDI₂, to a second processor 336. Therefore, the signal, TDO₁, output by the first processor 304 may serve as an input signal, TDI₂, for the second processor 336.

The second processor 336 may be coupled to the output of a sixth 338 and seventh multiplexer 340. The sixth multiplexer 338 may be coupled to and receive input from the first plurality of input lines 312, 314. Therefore, TMS may be input by the sixth multiplexer 338 using each of the first plurality of input lines 312, 314. Similarly, the seventh multiplexer 340 may be coupled to and receive input from the third plurality of input lines 320, 322. Therefore, TCK may be input by the seventh multiplexer 340 using each of the third plurality of input lines 320, 322.

The second processor 336 may be coupled to the first plurality of output lines 324, 326, which are coupled to and may provide signals, such as ATTN, output by the first 304 or second processor 336 to the fourth multiplexer 328. The second processor 336 may be coupled to a third plurality of output lines 342, 344, which are coupled to and provide signals, such as TDO₂, to an eighth multiplexer 346. Therefore, the third plurality of output lines 342, 344 may serve as input lines for the eighth multiplexer 346. The eighth multiplexer 346 may be coupled to and provide an output signal to a fifth pin of the connector interface 104, which may provide the output signal to the service processor 106. The signal output by the eighth multiplexer 346 may serve as a test result.

The IC 302 may also include a ninth multiplexer 348 which is coupled to the connector interface 104 (e.g., via a pin). Similar to the third multiplexer 114 of the first exemplary circuit 100, the ninth multiplexer 348 may receive bits from the service processor 106 as input signals. Outputs of the ninth multiplexer 348 may be coupled to the first through eighth multiplexers 306-310, 328, 334, 338-340, 346, respectively. More specifically, based on bits provided by the service processor 106, the ninth multiplexer 348 may output a different one of a plurality of signals to each of the first through eighth multiplexers 306-310, 328, 334, 338-340, 346 that serves as a select signal. The first through eighth multiplexers 306-310, 328, 334, 338-340, 346 operate in a similar manner. Based on a select signal input by the multiplexer, the multiplexer may selectively output a signal input, via one of a plurality of lines, by the multiplexer.

The operation of the second exemplary circuit 300 for testing an IC 302 is now described with reference to FIG. 3 and with reference to FIG. 2. With reference to FIG. 2, in step 202, the method 200 begins. In step 204, one of a plurality of input lines may be employed to receive a test signal for a processor. More specifically, the service processor 106, via the connector interface 104, may apply a test signal, TMS, on each of the first plurality of input lines 312, 314. Similarly, test signals TDI₁ and TCK may be applied on each of the second 316, 318 and third plurality of input lines 320, 322, respectively. In this manner, the first processor 304 may receive a test pattern of data. Other signals may be applied on the pluralities of input lines.

As described above, based on select signals input by the first, second and third multiplexers 306, 308, 310, respectively, each of the first, second and third multiplexers 306, 308, 310 may select one of the plurality of input lines to which the multiplexers 306, 308, 310 are connected to receive a test signal for the processor 304. Similarly, the sixth 338 and seventh multiplexers 340, which are coupled to the first 312, 314 and third plurality of input lines 320, 322, respectively, may each select one of the plurality of input lines to which the multiplexers 338, 340 are connected to receive a test signal for the processor 336 based on select signals input by the sixth 338 and seventh multiplexers 340, respectively.

In step 206, one of a plurality of output lines may be employed to send a test result from the processor. After sending test signals to the second exemplary circuit 300, the service processor 106 may issue a command for each processor to output signals representing a portion of the test pattern of data and a processor ID. Such signals output by the first processor 304 (e.g., TDO₁) may serve as a portion of a first test result. For example, the first processor 304 may apply the first test result to each of the second plurality of output lines 330, 332, which is coupled to and serves as an input for the fifth multiplexer 334. The first processor 304 may apply a signal (e.g., ATTN), which may indicate an error condition during the portion of the test performed on the first processor 304 and may serve as another portion of the first test result, to each of the first plurality of output lines 324, 326, which are coupled to and may serve as an input for the fourth multiplexer 328. Based on select signals input by the fourth 328 and fifth multiplexers 334, respectively, each of the fourth 328 and fifth multiplexers 334 may select one of the plurality of output lines to which the multiplexers 328, 334 are connected.

A portion of the test result (e.g., first test result) received from the selected output line may be transmitted. For example, TDO₁ output by the first processor may be transmitted to the second processor 336 and serve as an input signal, TDI₂. In one embodiment, the second processor 336 may receive a portion of the pattern of data output by the service processor 106 to the first processor 304 and the processor ID of the first processor 304. Similarly, ATTN output by the first processor 304 may be transmitted to the service processor 106 via the connector interface 104.

Similar to the first processor 304, the second processor 336 may apply a portion of a second test result (e.g., TDO₂) to each of the third plurality of output lines 342, 344. The portion of the second test result (e.g., TDO₂) may be based on the first test result output by the first processor 304 and TMS and TCK provided by service processor 106 to the second processor 336. For example, the second processor 336 may receive the processor ID of the first processor 304 and a portion of the pattern of data provided by the service processor 106 to the first processor 304, and apply the processor ID of the first processor 304 and second processor 336 and a portion of the pattern of data on each of the third plurality of output lines 342, 344, which may serve as an input for the eighth multiplexer 346. The second processor 336 may apply a signal (e.g., ATTN), which may indicate an error condition during the portion of the test performed on the second processor 336 and may serve as another portion of the second test result, to each of the first plurality of output lines 324, 326.

Based on select signals input by the fourth 328 and eighth multiplexers 346, respectively, each of the fourth 328 and eighth multiplexers 346 may select one of the plurality of output lines to which the multiplexers 328, 346 are connected. A portion of the second test result received from the selected output lines, respectively, may be transmitted. For example, TDO₂ output by the second processor 336 may be transmitted to the service processor 106. In one embodiment, the service processor 106 may receive the processor ID of each processor included in the second exemplary circuit 300 (e.g., the ID of the first processor 304 and second processor 336) and a portion of the pattern of data provided to the second exemplary circuit 300 by the service processor 106. Similarly, ATTN may be output by the second processor 336 and transmitted to the service processor 106 via the connector interface 104.

In this manner, the second exemplary circuit 300 may receive (e.g., from the service processor 106) a pattern of data and output processor IDs and a portion of the pattern of data as a portion of the test result (e.g., to the service processor 106). The service processor 106 may also receive ATTN as a portion of the test result. In step 208, it is determined whether the result of the test performed on the IC 302 was successful. The service processor 106 may compare one or more portions of the test result received from the second exemplary circuit 300 with the pattern of data provided to the second exemplary circuit 300 to make the determination. For example, if the second exemplary circuit 300 receives a pattern of data (e.g., which includes non-zero characters), but outputs all zeros or some processor IDs and zeros, the test on the IC 302 is determined to be unsuccessful. Thereafter, step 210 is performed. In step 210, it is determined whether a remaining one of the plurality of input lines may be employed to receive a test signal and/or data for one or more of the processors 304, 336 or a remaining one of the plurality of output lines may be employed to send a test result from one or more of the processors 304, 336. Because step 210 was described above in detail, it will not be described in detail herein.

If it is determined in step 210 that a remaining one of the plurality of input lines may be employed to receive a test signal and/or data for one or more of the processors 304, 336 or a remaining one of the plurality of output lines may be employed to send a test result from one or more of the processors 304, 336, step 212 may be performed. In step 212, at least one of employing a remaining one of the plurality of input lines to receive a test signal for one or more of the processors 304, 336 and employing a remaining one of the plurality of output lines to send a test result from one or more of the processors 304, 336 is performed. In one embodiment, an algorithm may be used for determining which remaining input line from one or more of the first through fifth plurality of input lines to employ for receiving a test signal for one or more of the processors and/or which remaining output line from one or more of the first through third plurality of output lines to employ to send a test result from one or more of the processors. It is assumed in the example below each of the pluralities of input lines and output lines includes a primary line and a secondary line, and the second exemplary circuit 300 initially employs the primary line of each of the first through fifth plurality of input lines and the first through third plurality of output lines. If the test performed on the IC 302 using such a combination of input and output lines is unsuccessful, another combination of input lines and output lines may be employed by the second exemplary circuit 300 during the testing.

For example, if the initial test result includes all zeroes, bits provided to the ninth multiplexer 348, and therefore, the select signals output by the ninth multiplexer 348, may be modified such that the secondary input line of the third plurality of input lines 320, 322 may be employed to receive the TCK signal for the first processor 304 and/or the second processor 336 during a subsequent test (e.g., a second test) of the IC 302. Alternatively, if the initial test result includes one or more processor IDs and zeroes, bits provided to the ninth multiplexer 348, and therefore, the select signals output by the ninth multiplexer 348, may be modified such that the secondary input line of the second plurality of input lines 316, 318 and the secondary output line of the second 330, 332 and/or third plurality 342, 344 of output lines may be employed for receiving TDI₁ for the first processor 304 and sending TDO₁ from the first processor 304 and/or sending TDO₂ from the second processor 336 during a subsequent test (e.g., a second test) of the IC 302.

If the result of the second test is unsuccessful, bits provided to the ninth multiplexer 348, and therefore, the select signals output by the ninth multiplexer 348, may be modified such that the secondary input line of the third plurality of input lines 320, 322, the secondary input of line the second plurality of input lines 316, 318, and the secondary output line of the third plurality of output lines 342, 344 may be employed to receive TCK for the first processor 304 and/or the second processor 336, receive TDI₁ for the first processor 304 and send TDO₂ from the second processor 336 during a subsequent test (e.g., a third test) of the IC 302.

If the result of the third test is unsuccessful, bits provided to the ninth multiplexer 348, and therefore, the select signals output by the ninth multiplexer 348, may be modified such that the secondary input line of the first plurality of input lines 312, 314, the primary input line of the second plurality of input lines 316, 318, the primary input line of the third plurality of input lines 320, 322 and the primary output line of the second 330, 332 and/or third plurality of output lines 342, 344 may be employed to receive TMS for the first 304 and/or second processor 336, receive TDI₁ for the first processor 304, receive TCK for the first 304 and/or second processor 336, and send TDO₁ from the first processor and/or TDO₂ from the second processor 336 during a subsequent test (e.g., a fourth test) of the IC 302.

If the result of the fourth test is unsuccessful, bits provided to the ninth multiplexer 348, and therefore, the select signals output by the ninth multiplexer 348, may be modified such that the secondary line of the first plurality of input lines 312, 314, the secondary line of the third plurality of input lines 320, 322, the secondary input line of second plurality of input lines 316, 318, and the secondary output line of the second plurality of output lines 330, 332 and/or the third plurality of output lines 342, 344 may be employed to receive TMS for the first 304 and/or second processor 336, receive TCK for the first 304 and/or second processor 336, receive TDI₁ for the first processor 304, and send TDO₁ from the first processor 304 and/or TDO₂ from the second processor 336 during a subsequent test (e.g., a fifth test) of the IC 302. The primary or the secondary output line of the first plurality of output lines 324, 326 may be employed during any of the above tests such that ATTN received from the first 304 or second processor 336 is sent to the service processor 106.

The IC 302 may be tested in the manner described above until a test result is successful. Thereafter, step 214 is performed in which the method 200 ends. As stated above, such testing may be performed during an initial program load (IPL) or another time. The bits sent to the ninth multiplexer 348 of the second exemplary circuit 300 that yield a successful test result may be stored such that the bits may be used for testing the IC 302 in the future.

Alternatively, if the above algorithm does not yield a successful test result, no remaining input lines and/or output lines of the IC 302 may be employed during a subsequent test to yield a successful result. Therefore, the IC 302 and/or card which includes the IC 302 may be faulty. Thereafter, step 214 is performed in which the method 200 ends.

Through the use of the methods of testing (e.g., JTAG testing) an IC 102, 302, in response to an unsuccessful test result using a combination of an input line from each of one or more pluralities of input lines coupled to one or more processors and an output line from each of one or more pluralities of output lines coupled to one or more of the processors, a different combination of input lines and/or output lines may be employed during a subsequent test, until the test result is successful. In this manner, by providing redundancy in the input lines used for receiving a test signal and/or data for one or more of the processors and redundancy in the output lines used for transmitting a test result from one or more of the processors, the IC or card which includes the IC will not fail if one of the input lines and/or one of the output lines fails (e.g., because of a short circuit or a break in the line). Therefore, the present methods and apparatus may increase the manufacturing yield of the IC or the card which includes the IC.

The foregoing description discloses only exemplary embodiments of the invention. Modifications of the above disclosed methods and apparatus which fall within the scope of the invention will be readily apparent to those of ordinary skill in the art. For instance, although in the above embodiments, the same test signal and/or data is applied to each of a plurality of input lines, in other embodiments, a different test signal may be applied to each of the plurality of input lines. Further, although in the above embodiments, bits are provided by the service processor 106 via a serial transmission to a multiplexer 114, 348 included in the circuit 100, 300 for testing an IC 102, 302, in other embodiments, the bits may be transmitted in parallel. Although in the above embodiments, the service processor 106 provides bits to a multiplexer 114, 348 which outputs select signals, in other embodiments, another device may be used for providing such bits. Although in the above embodiments, a specific algorithm is used for determining a combination of input and/or output lines employed during IC testing, in other embodiments, different algorithms may be used.

Accordingly, while the present invention has been disclosed in connection with exemplary embodiments thereof, it should be understood that other embodiments may fall within the spirit and scope of the invention as defined by the following claims.

1. A method for testing an integrated circuit (IC) comprising:
employing one of a plurality of input lines to receive a test signal for a processor;
employing one of a plurality of output lines to send a test result from the processor; and
if the test result is unsuccessful, performing at least one of:
employing a remaining one of the plurality of input lines to receive the test signal for the processor; and
employing a remaining one of the plurality of output lines to send the test result from the processor.

2. The method of claim 1 wherein employing one of the plurality of input lines to receive the test signal for the processor includes:
applying the test signal to each of the plurality of input lines;
selecting one of the plurality of input lines; and
receiving the test signal for the processor from the selected input line.

3. The method of claim 1 wherein employing one of the plurality of output lines to send the test result from the processor includes:
applying the test result to each of the plurality of output lines;
selecting one of the plurality of output lines; and
sending the test result from the processor using the selected output line.

4. The method of claim 1 wherein employing a remaining one of the plurality of input lines to receive the test signal for the processor includes:
selecting a remaining one of the plurality of input lines; and
employing the selected remaining one of the plurality of input lines to receive the test signal.

5. The method of claim 4 wherein selecting a remaining one of the plurality of input lines includes:
modifying a first select signal; and
selecting a remaining one of the plurality of input lines based on the modified first select signal.

6. The method of claim 1 wherein employing a remaining one of the plurality of output lines to send the test result from the processor includes:
selecting a remaining one of the plurality of output lines; and
employing the selected remaining one of the plurality of output lines to send the test result from the processor.

7. The method of claim 6 wherein selecting a remaining one of the plurality of output lines includes:
modifying a second select signal; and
selecting a remaining one of the plurality of output lines based on the modified second select signal.

8. The method of claim 1 wherein:
employing a remaining one of the plurality of input lines to receive the test signal for the processor includes:
selecting a remaining one of the plurality of input lines; and
employing the selected remaining one of the plurality of input lines to receive the test signal; and
employing a remaining one of the plurality of output lines to send the test result from the processor includes:
selecting a remaining one of the plurality of output lines; and
employing the selected remaining one of the plurality of output lines to send the test result from the processor.

9. The method of claim 8 wherein:
selecting a remaining one of the plurality of input lines includes:
modifying a first select signal; and
selecting a remaining one of the plurality of input lines based on the modified first select signal; and
selecting a remaining one of the plurality of output lines includes:
modifying a second select signal; and
selecting a remaining one of the plurality of output lines based on the modified second select signal.

10. An apparatus for testing an IC comprising:
a processor;
a plurality of input lines coupled to the processor;
a plurality of output lines coupled to the processor; and
a connector interface coupled to the plurality of input lines and the plurality of output lines;
wherein the apparatus is adapted to:
employ one of the plurality of input lines to receive a test signal for the processor;
employ one of the plurality of output lines to send a test result from the processor; and
if the test result is unsuccessful, perform at least one of:
employing a remaining one of the plurality of input lines to receive the test signal for the processor; and
employing a remaining one of the plurality of output lines to send the test result from the processor.

11. The apparatus of claim 10 wherein the connector interface is adapted to apply the test signal to each of the plurality of input lines; and
further comprising a first multiplexer coupled to the plurality of input lines and the processor, and adapted to:
select one of the plurality of input lines; and
receive the test signal for the processor on the selected input line.

12. The apparatus of claim 11 wherein the first multiplexer is further adapted to:
select a remaining one of the plurality of input lines; and
employ the selected remaining one of the plurality of input lines to receive the test signal.

13. The apparatus of claim 11 further comprising a third multiplexer coupled to the connector interface and first multiplexer, and adapted to modify a first select signal, the first select signal corresponding to the first multiplexer; and
wherein the first multiplexer is further adapted to select a remaining one of the plurality of input lines based on the modified first select signal.

14. The apparatus of claim 10 wherein the processor is adapted to apply the test result to each of the plurality of output lines; and
further comprising a second multiplexer coupled to the plurality of output lines and the connector interface, and adapted to:
select one of the plurality of output lines; and
send the test result from the processor using the selected output line.

15. The apparatus of claim 14 wherein the second multiplexer is further adapted to:
select a remaining one of the plurality of output lines; and
employ the selected remaining one of the plurality of output lines to send the test result from the processor.

16. The apparatus of claim 15 further comprising a third multiplexer coupled to the connector interface and second multiplexer, and adapted to modify a second select signal, the second select signal corresponding to the second multiplexer; and
wherein the second multiplexer is further adapted to select a remaining one of the plurality of output lines based on the modified second select signal.

17. The apparatus of claim 10 wherein the connector interface is adapted to apply the test signal to each of the plurality of input lines; and
further comprising a first multiplexer coupled to the plurality of input lines and the processor, the first multiplexer adapted to:
select one of the plurality of input lines; and
receive the test signal for the processor from the selected input line;
wherein the processor is further adapted to apply the test result to each of the plurality of output lines; and
further comprising a second multiplexer coupled to the plurality of output lines and the connector interface, the second multiplexer adapted to:
select one of the plurality of output lines; and
send the test result from the processor using the selected output line.

18. The apparatus of claim 17 wherein:
the first multiplexer is further adapted to:
select a remaining one of the plurality of input lines; and
employ the selected remaining one of the plurality of input lines to receive the test signal; and
the second multiplexer is further adapted to:
select a remaining one of the plurality of output lines; and
employ the selected remaining one of the plurality of output lines to send the test result from the processor.

19. The apparatus of claim 18 further comprising a third multiplexer coupled to the connector interface, first multiplexer and second multiplexer, and adapted to:
modify a first select signal, the first select signal corresponding to the first multiplexer; and
modify a second select signal, the second select signal corresponding to the second multiplexer; and
wherein the first multiplexer is further adapted to select a remaining one of the plurality of input lines based on the modified first select signal; and
wherein the second multiplexer is further adapted to select a remaining one of the plurality of output lines based on the modified second select signal.

20. The apparatus of claim 10 wherein the connector interface is adapted to couple to a service processor.
